(19) United States
(12) Patent Application Publication
(10) Pub. No.: US 2017/0040477 A1
(43) Pub. Date: Feb. 9, 2017

(54) SEMICONDUCTOR LAYERED STRUCTURE AND PHOTODIODE

(71) Applicant: Sumitomo Electric Industries, Ltd., Osaka-shi (JP)

(72) Inventors: Suguru Arikata, Itami-shi (JP); Takashi Kyono, Itami-shi (JP); Koji Nishizuka, Itami-shi (JP); Kaoru Shibata, Itami-shi (JP); Katsushi Akita, Itami-shi (JP)

(73) Assignee: Sumitomo Electric Industries, Ltd., Osaka (JP)

(21) Appl. No.: 15/304,805

(22) PCT Filed: Dec. 17, 2014
(86) PCT No.: PCT/JP2014/083378

§ 371 Date: Oct. 17, 2016

(30) Foreign Application Priority Data
Apr. 24, 2014 (JP) 2014-089743

(51) Int. Cl. H01L 31/0352; H01L 31/18; H01L 31/0224; H01L 31/0216; H01L 31/0304; H01L 31/109

(52) U.S. Cl. CPC H01L 31/035236; H01L 31/03046; H01L 31/109; H01L 31/022408; H01L 31/02161; H01L 31/1844

(57) ABSTRACT

A semiconductor layered structure according to the present invention includes a substrate formed of a III-V compound semiconductor; and semiconductor layers disposed on the substrate and formed of III-V compound semiconductors. The substrate has a majority-carrier-generating impurity concentration of 1×10¹⁷ cm⁻³ or more and 2×10²⁰ cm⁻³ or less, and the impurity has an activation ratio of 30% or more.

### TECHNICAL FIELD

The present invention relates to a semiconductor layered structure and a photodiode, more specifically to a semiconductor layered structure and a photodiode that include a substrate formed of a III-V compound semiconductor.

### BACKGROUND ART

Operation layers formed of III-V compound semiconductors are formed on a substrate formed of a III-V compound semiconductor, to thereby provide a photodiode for infrared light. Thus, in order to develop such photodiodes used for, for example, communications, tests on living bodies, or image capturing at night, various studies have been performed on photodiodes including a substrate and operation layers formed of III-V compound semiconductors. For example, Non Patent Literature 1 has reports including production of a photodiode having a cutoff wavelength of 2.39 μm by forming a type-II quantum well structure as an absorption layer on an InP (indium phosphide) substrate, the quantum well structure being constituted by the combination of InGaAs (indium gallium arsenide) layers and GaAsSb (gallium arsenide antimonide) layers. In addition, for example, Patent Literatures 1 to 3 have proposed that, in a photodiode in which an absorption layer formed of a III-V compound semiconductor is formed on an InP substrate, for the purpose of achieving enhancement of light transmittance of the substrate and reduction in the dark current in the photodiode, the carrier concentration of the substrate is set to be within a predetermined range.

### CITATION LIST

### Patent Literature

PTL 1: Japanese Unexamined Patent Application Publication No. 2-244771
PTL 2: Japanese Unexamined Patent Application Publication No. 4-255274
PTL 3: Japanese Unexamined Patent Application Publication No. 10-261813

### Non Patent Literature

NPL 1: R. Sidhu, et al., “A 2.3 μm CUTOFF WAVELENGTH PHOTODIODE ON InP USING LATTICE-MATCHED GaInAs—GaAsSb TYPE-II QUANTUM WELLS”, 2005 International Conference on Indium Phosphide and Related Materials, p. 148-151

### SUMMARY OF INVENTION

### Technical Problem

In recent years, there has been a demand for such a photodiode that has higher sensitivity and incurs lower power consumption, for example. However, the above-described approach of setting the carrier concentration is sometimes difficult to ensure sufficient sensitivity and also to achieve reduction in the power consumption.

Accordingly, an object is to provide a semiconductor layered structure and a photodiode that enable the photodiode to have sufficient sensitivity and also to achieve reduction in the power consumption.

### Solution to Problem

A semiconductor layered structure according to the present invention includes a substrate formed of a III-V compound semiconductor: and a semiconductor layer disposed on the substrate and formed of a III-V compound semiconductor. The substrate has a majority-carrier-generating impurity concentration of 1×10¹⁷ cm⁻³ or more and 2×10²⁰ cm⁻³ or less, and the impurity has an activation ratio of 30% or more.

### Advantageous Effects of Invention

The above-described semiconductor layered structure can provide a semiconductor layered structure that enables a photodiode to have sufficient sensitivity and also to achieve reduction in the power consumption.

### BRIEF DESCRIPTION OF DRAWINGS

FIG. 1 is a schematic sectional view illustrating an example of the structure of a semiconductor layered structure.

FIG. 2 is a schematic sectional view illustrating an example of the structure of a photodiode.

FIG. 3 is a flow chart schematically illustrating a method for producing a semiconductor layered structure and a photodiode.

FIG. 4 is a schematic sectional view illustrating an example of a method for producing a semiconductor layered structure and a photodiode.

FIG. 5 is a schematic sectional view illustrating an example of a method for producing a semiconductor layered structure and a photodiode.

FIG. 6 is a schematic sectional view illustrating an example of a method for producing a semiconductor layered structure and a photodiode.

FIG. 7 is a schematic sectional view illustrating an example of a method for producing a semiconductor layered structure and a photodiode.

FIG. 8 is a schematic sectional view illustrating the structure of an experimental device.

FIG. 9 is a graph indicating the relationship between majority-carrier-generating impurity concentration and power consumption.

### DESCRIPTION OF EMBODIMENTS

### Description of Embodiments According to the Invention of the Present Application

Embodiments according to the invention of the present application will be first listed and described. A semiconductor layered structure according to the present application includes a substrate formed of a III-V compound semiconductor; and a semiconductor layer disposed on the substrate and formed of a III-V compound semiconductor. The substrate has a majority-carrier-generating impurity (impurity added for generating majority carriers) concentration of 1×10¹⁷ cm⁻³ or more and 2×10²⁰ cm⁻³ or less, and the impurity has an activation ratio of 30% or more.

The inventors of the present invention performed studies on how to impart sufficient sensitivity to a photodiode and also to achieve reduction in the power consumption. As a result, the inventors have found the following findings. In a photodiode that has a structure in which a semiconductor layer formed of a III-V compound semiconductor and serving as an operation layer is formed on a substrate formed of a III-V compound semiconductor, and that detects light through carrier transfer in the thickness direction of the substrate, the carrier concentration of the substrate considerably affects the power consumption. Specifically, an increase in the carrier concentration (majority-carrier concentration) of the substrate enables reduction in the power consumption of the photodiode. On the other hand, an increase in the carrier concentration of the substrate results in a decrease in the sensitivity of the photodiode. This is because an increase in the carrier concentration results in an increase in free-carrier absorption in the substrate. Accordingly, an appropriate adjustment of the carrier concentration of the substrate may provide sufficient sensitivity and also enable reduction in the power consumption.

However, according to studies preformed by the inventors of the present invention, even when substrates have equivalent carrier concentrations, variations in the sensitivity are observed between the photodiodes. Specifically, even when substrates have equivalent carrier concentrations, a low activation ratio of the majority-carrier-generating impurity in such a substrate results in a decrease in the sensitivity of the photodiode. In addition, even when substrates have equivalent majority-carrier-generating impurity concentrations, variations in the sensitivity are observed between the photodiodes. Specifically, even when substrates have equivalent majority-carrier-generating impurity concentrations, a low activation ratio of the majority-carrier-generating impurity in such a substrate results in a decrease in the sensitivity of the photodiode. The reason for this is probably, for example, as follows. When the activation ratio is low, a high impurity concentration is required to achieve such an equivalent carrier concentration. Such a high impurity concentration results in high free-carrier absorption. In addition, unactivated impurity atoms are not at appropriate positions in crystals. For this reason, even when substrates have equivalent majority-carrier-generating impurity concentrations, a low activation ratio results in low crystallinity of such a substrate, which results in a further decrease in the sensitivity of the photodiode. In summary, in order to impart sufficient sensitivity to a photodiode and also to achieve reduction in the power consumption, it is important that the majority-carrier-generating impurity concentration of the substrate is set to ensure a carrier concentration enabling reduction in the power consumption, and that the activation ratio is set to a predetermined value or more to reduce the amount of unactivated impurity, which causes a decrease in the sensitivity.

In the semiconductor layered structure according to the present application, the substrate has a majority-carrier-generating impurity concentration of 1×10¹⁷ cm⁻³ or more and 2×10²⁰ cm⁻³ or less, and the impurity has an activation ratio of 30% or more. These numerical ranges are defined for the following reasons. In order to adjust the power consumption to be within the allowable range, the majority-carrier-generating impurity concentration needs to be set to 1×10¹⁷ cm⁻³ or more. On the other hand, when the impurity concentration is more than 2×10²⁰ cm⁻³, even in the case of a high activation ratio, the unactivated impurity concentration increases, which results in a decrease in the sensitivity. For this reason, the impurity concentration of the substrate needs to be set to 2×10²⁰ cm⁻³ or less. When the majority-carrier-generating impurity concentration is 1×10¹⁷ cm⁻³ or more and 2×10²⁰ cm⁻³ or less and the majority-carrier-generating impurity has an activation ratio of less than 30%, the unactivated impurity concentration increases, which results in a decrease in the sensitivity. For this reason, the activation ratio of the impurity needs to be set to 30% or more. In the semiconductor layered structure according to the present application, the majority-carrier-generating impurity concentration of the substrate and the activation ratio of the impurity are set to be within the above-described ranges, to thereby ensure a carrier concentration that enables achievement of reduction in the power consumption, and also to achieve a decrease in the amount of unactivated impurity, which causes a decrease in the sensitivity. As a result, when the semiconductor layered structure according to the present application is used to produce a photodiode, sufficient sensitivity can be ensured and reduction in the power consumption can be achieved.

In the semiconductor layered structure, in order to further reduce the power consumption, the majority-carrier-generating impurity concentration of the substrate is preferably set to 1×10¹⁸ cm⁻³ or more. In addition, in order to obtain sufficient sensitivity with more certainty, the majority-carrier-generating impurity concentration of the substrate is preferably set to 1×10²⁰ cm⁻³ or less, more preferably set to 1×10¹⁹ cm⁻³ or less. Furthermore, in order to obtain sufficient sensitivity with more certainty, the activation ratio of the majority-carrier-generating impurity of the substrate is preferably set to 50% or more, more preferably set to 80% or more.

In the semiconductor layered structure, the substrate may have an n-type conductivity. In this case, the majority carriers of the substrate are electrons, which enables a high operation speed of the photodiode, compared with the case where the majority carriers are holes.

In the semiconductor layered structure, the semiconductor layer may include a quantum well layer. The semiconductor layer includes a quantum well layer that functions as an absorption layer, to thereby obtain a semiconductor layered structure usable for producing a photodiode configured to detect light of desired wavelengths.

In the semiconductor layered structure, the quantum well layer may have a thickness of 1 μm or more. In this case, when the semiconductor layered structure is used to produce a photodiode, the photodiode can have increased sensitivity.

In the semiconductor layered structure, the quantum well layer may have a structure in which an InₓGa₁₋ₓAs (indium gallium arsenide, 0.38≦x≦1) layer and a GaAs_{1-y}Sb_{y}(gallium arsenide antimonide, 0.36≦y≦1) layer are alternately stacked, or may have a structure in which a Ga₁₋ᵤInᵤNᵥAs₁₋ᵥ (gallium indium nitride arsenide, 0.4≦u≦0.8, 0<v≦0.2) layer and a GaAs_{1-y}Sb_{y} (gallium arsenide antimonide. 0.36≦y≦0.62) layer are alternately stacked. A quantum well layer having such a structure is suitable as an infrared absorption layer for the near-infrared to mid-infrared range of wavelengths of 2 to 10 μm. For this reason, such a configuration can provide a semiconductor layered structure suitable for producing an infrared photodiode for the near-infrared to mid-infrared range.

In the semiconductor layered structure, the III-V compound semiconductor forming the substrate may be GaAs (gallium arsenide), GaP (gallium phosphide), GaSb (gallium antimonide), InP (indium phosphide), InAs (indium arsenide), InSb (indium antimonide), AlSb (aluminum antimonide), or AlAs (aluminum arsenide). Semiconductor layered structures including substrates formed of such III-V compound semiconductors are suitable as semiconductor layered structures for producing infrared photodiodes.

In the semiconductor layered structure, the semiconductor layer may be formed by metal-organic vapor phase epitaxy. This enables efficient formation of a semiconductor layer of high crystal quality.

A photodiode according to the present application includes the above-described semiconductor layered structure according to the present application, and an electrode formed on a main surface of the substrate of the semiconductor layered structure, the main surface being on a side of the substrate opposite to the semiconductor layer. The photodiode according to the present application includes the above-described semiconductor layered structure according to the present application. For this reason, the photodiode according to the present application has sufficient sensitivity and also enables reduction in the power consumption.

### Details of Embodiments According to the Invention of the Present Application

Hereinafter, a semiconductor layered structure according to an embodiment of the present invention will be described with reference to drawings. Note that the same or corresponding parts in the drawings below are denoted by the same reference sign and the description thereof will not be repeated.

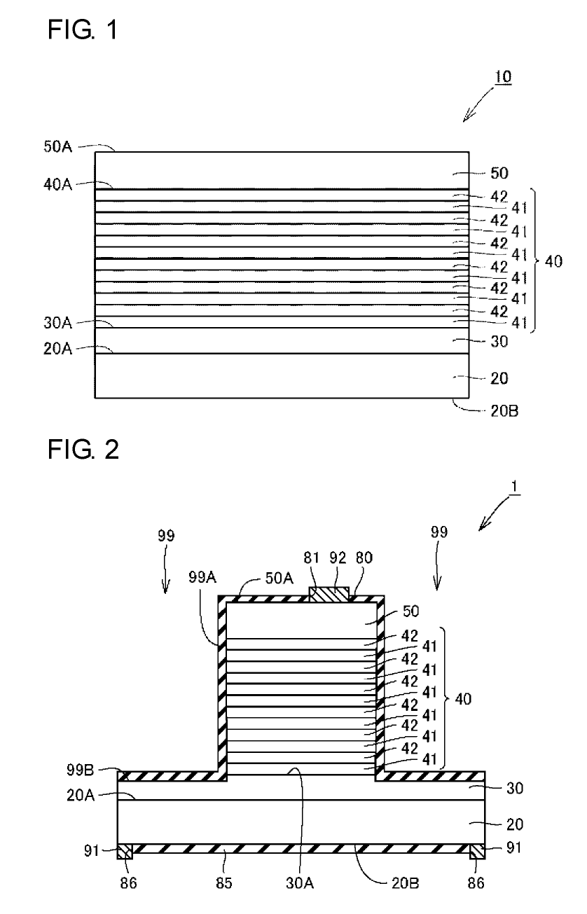

Referring to FIG. 1, a semiconductor layered structure 10 of the embodiment includes a substrate 20, a buffer layer 30, a quantum well layer 40, and a contact layer 50. The buffer layer 30, the quantum well layer 40, and the contact layer 50 constitute the semiconductor layers of the embodiment. The semiconductor layers disposed on the substrate 20 include the quantum well layer 40, so that the semiconductor layered structure 10 of the embodiment is usable for producing a photodiode configured to detect light of desired wavelengths.

The substrate 20 is formed of a III-V compound semiconductor. The substrate 20 can have a diameter of 55 mm or more, for example, 3 inches. Examples of the III-V compound semiconductor forming the substrate 20 include GaAs, GaP, GaSb, InP, InAs, InSb, AlSb, and AlAs. The substrate 20 formed of such a III-V compound semiconductor is employed to thereby provide the semiconductor layered structure 10 suitable for production of infrared photodiodes. For the purpose of increasing the production efficiency and yield of photodiodes from the semiconductor layered structure 10, the diameter of the substrate 20 may be 80 mm or more (for example, 4 inches), may be 105 mm or more (for example, 5 inches), or may be 130 mm or more (for example, 6 inches).

The buffer layer 30 is disposed on and in contact with a main surface 20A, which is one of the main surfaces of the substrate 20.

The buffer layer 30 is formed of a III-V compound semiconductor. Examples of the III-V compound semiconductor forming the buffer layer 30 include GaAs, GaP, GaSb, InP, InAs, InSb, AlSb, AlAs, AlGaAs (aluminum gallium arsenide), InGaAs (indium gallium arsenide), and InGaP (indium gallium phosphide). Specifically, for example, InGaAs of n-type conductivity (n-InGaAs) is employed as the compound semiconductor forming the buffer layer 30. As the n-type impurity contained in the buffer layer 30, for example, Si (silicon) can be employed.

The quantum well layer 40 is disposed on and in contact with a main surface 30A of the buffer layer 30, the main surface 30A being on a side of the buffer layer 30 opposite to the other side facing the substrate 20. The quantum well layer 40 has a structure in which two component layers formed of III-V compound semiconductors are alternately stacked. More specifically, the quantum well layer 40 has a structure in which a first component layer 41 and a second component layer 42 are alternately stacked.

The III-V compound semiconductor forming the first component layer 41 may be, for example, InₓGa₁₋ₓAs (0.38≦x≦1); and the III-V compound semiconductor forming the second component layer 42 may be, for example, GaAs_{1-y}Sb_{y} (0.36≦y≦1). Alternatively, the III-V compound semiconductor forming the first component layer 41 may be Ga₁₋ᵤInᵤNᵥAs₁₋ᵥ (0.4≦u≦0.8, 0<v≦0.2); and the III-V compound semiconductor forming the second component layer 42 may be GaAs_{1-y}Sb_{y} (0.36≦y≦0.62). In such cases, the semiconductor layered structure 10 of the embodiment is prepared as being suitable for producing an infrared photodiode for the near-infrared to mid-infrared range.

The first component layer 41 and the second component layer 42 may each have a thickness of 5 nm, for example. The quantum well layer 40 may have, for example, a stack of 250 unit structures each constituted by the first component layer 41 and the second component layer 42. Thus, the quantum well layer 40 may have a thickness of, for example, 2.5 μm. The quantum well layer 40 may be formed as a type-II quantum well having such a structure. When the quantum well layer 40 is formed so as to have a thickness of 1 μm or more, the photodiode produced with the semiconductor layered structure 10 can have increased sensitivity.

Incidentally, the combination of the III-V compound semiconductors forming the first component layer 41 and the second component layer 42 is not limited to the combination of InGaAs and GaAsSb and the combination of GaInNAs and GaAsSb. Examples of the combination of the III-V compound semiconductors include a combination of GaAs (gallium arsenide) and AlGaAs (aluminum gallium arsenide), a combination of InAs (indium arsenide) and InAsSb (indium arsenide antimonide), a combination of GaN (gallium nitride) and AlGaN (aluminum gallium nitride), and a combination of InGaN (indium gallium nitride) and AlGaN (aluminum gallium nitride).

The contact layer 50 is disposed on and in contact with a main surface 40A of the quantum well layer 40, the main surface 40A being on a side of the quantum well layer 40 opposite to the other side facing the buffer layer 30. The contact layer 50 is formed of a III-V compound semiconductor.

Examples of the III-V compound semiconductor forming the contact layer 50 include GaAs, InP, and InGaAs. Specifically, for example, InGaAs of p-type conductivity (p-InGaAs) is employed as the compound semiconductor forming the contact layer 50. As the p-type impurity contained in the contact layer 50, for example, Zn (zinc) may be employed.

The substrate 20 has a majority-carrier-generating impurity concentration of 1×10¹⁷ cm⁻³ or more and 2×10²⁰ cm⁻³ or less, and the impurity has an activation ratio of 30% or more. Specifically, the III-V compound semiconductor forming the substrate 20 may be, for example, InP. The majority-carrier-generating impurity of the substrate 20 may be, for example, S (sulfur). In this case, the substrate 20 has an n-type conductivity. Alternatively, the substrate 20 may have a p-type conductivity: however, when the substrate 20 has an n-type conductivity, the majority carriers of the substrate 20 are electrons, which enables a high operation speed of the photodiode, compared with the case where the majority carriers are holes.

The substrate 20 thus has a S (added as an impurity) concentration of 1×10¹⁷ cm⁻³ or more and 2×10²⁰ cm⁻³ or less, and the S has an activation ratio of 30% or more. This ensures, in the substrate 20, a carrier concentration that enables achievement of reduction in the power consumption, and also achieves reduction in the amount of unactivated impurity, which causes a decrease in the sensitivity. As a result, a photodiode produced with the semiconductor layered structure 10 of the embodiment has sufficient sensitivity and also achieves reduction in the power consumption.

Incidentally, the activation ratio of impurity is defined as (carrier concentration)/(majority-carrier-generating impurity concentration)×100(%). The majority-carrier-generating impurity concentration can be determined by SIMS (Secondary Ion Mass Spectrometry) or GDMS (Glow Discharge Mass Spectrometry). In the measurement of the majority-carrier-generating impurity concentration by SIMS or GDMS, sputtering is performed to dig the semiconductor layered structure 10 to thereby analyze the target site. At this time, sputtering may be performed to dig the semiconductor layers from the front surface (a main surface 50A of the contact layer 50) to the substrate 20, to thereby measure the substrate 20 for the majority-carrier-generating impurity concentration; alternatively, sputtering may be performed to dig the substrate 20 from its main surface 20B side, to thereby measure the substrate 20 for the majority-carrier-generating impurity concentration. Alternatively, after the semiconductor layers (buffer layer 30, quantum well layer 40, and contact layer 50) are removed by etching, the substrate 20 may be dug from its front surface, to thereby measure the substrate 20 for the majority-carrier-generating impurity concentration.

The carrier concentration can be determined by C-V (capacitance-voltage) measurement or Hall measurement. In the C-V measurement, electrolytic solution or metal may be used for a Schottky contact. When electrolytic solution is used for a Schottky contact, after etching is performed to dig the semiconductor layers from the front surface of the semiconductor layers (the main surface 50A of the contact layer 50) to the substrate 20, the C-V measurement may be performed; alternatively, the C-V measurement may be performed on the main surface 20B side of the substrate 20. Alternatively, after the semiconductor layers (buffer layer 30, quantum well layer 40, and contact layer 50) are removed by etching, the substrate 20 may be subjected to the C-V measurement. The C-V measurement may be performed while a voltage is applied to the semiconductor layered structure 10 to expand the depletion layer to the substrate 20. When metal is used for a Schottky contact, the measurement may be performed with electrodes formed of metals that form Schottky contacts, the electrodes being individually attached to the front surface of the semiconductor layers (the main surface 50A of the contact layer 50) and the main surface 20B of the substrate 20; alternatively, after the semiconductor layers are removed by etching, the measurement may be performed with such electrodes attached to the substrate 20. The Hall measurement can be performed in the following manner: after the semiconductor layers (buffer layer 30, quantum well layer 40, and contact layer 50) are removed by etching, the measurement is performed with electrodes attached to the substrate, the electrodes being formed of a metal that forms ohmic contacts with the substrate 20, such as In, Au—Zn (gold-zinc), or Ti/Al.

Hereinafter, an infrared photodiode (photodiode) will be described as an example of photodiodes produced from the above-described semiconductor layered structure 10. Referring to FIG. 2, an infrared photodiode 1 according to an embodiment is produced from the semiconductor layered structure 10 according to the above-described embodiment. As with the semiconductor layered structure 10, the infrared photodiode 1 includes the stack of a substrate 20, a buffer layer 30, a quantum well layer 40, and a contact layer 50. In the infrared photodiode 1, a trench 99 is formed so as to extend through the contact layer 50 and the quantum well layer 40 to reach the buffer layer 30.

Thus, on a side wall 99A of the trench 99, the contact layer 50 and the quantum well layer 40 are exposed. A bottom wall 99B of the trench 99 is positioned within the buffer layer 30.

The infrared photodiode 1 further includes a passivation film 80, an antireflective film 85, an n-electrode 91, and a p-electrode 92. The passivation film 80 is disposed so as to cover the bottom wall 99B of the trench 99, the side wall 99A of the trench 99, and a main surface 50A of the contact layer 50, the main surface 50A being on a side of the contact layer 50 opposite to the other side facing the quantum well layer 40. The passivation film 80 is formed of an insulator such as silicon nitride or silicon oxide. The antireflective film 85 is disposed so as to cover a main surface 20B of the substrate 20, the main surface 20B being on a side of the substrate 20 opposite to the buffer layer 30. The antireflective film 85 is formed of, for example, silicon oxynitride.

The antireflective film 85 has an opening 86 extending through the antireflective film 85 in the thickness direction. The n-electrode 91 is disposed so as to fill the opening 86. The n-electrode 91 is disposed so as to be in contact with the substrate 20 exposed through the opening 86. The n-electrode 91 is formed of an electric conductor such as metal. More specifically, the n-electrode 91 may be formed of, for example, AuGeNi (gold germanium nickel). The n-electrode 91 is in ohmic contact with the substrate 20.

The passivation film 80 covering the main surface 50A of the contact layer 50 has an opening 81 extending through the passivation film 80 in the thickness direction. The p-electrode 92 is disposed so as to fill the opening 81. The p-electrode 92 is disposed so as to be in contact with the contact layer 50 exposed through the opening 81. The p-electrode 92 is formed of an electric conductor such as metal. More specifically, the p-electrode 92 may be formed of, for example, AuZn (gold zinc). The p-electrode 92 is in ohmic contact with the contact layer 50.

When infrared rays enter the infrared photodiode 1 through the antireflective film 85, the infrared rays are absorbed between quantum levels within the quantum well layer 40, resulting in generation of electron-hole pairs. The generated electrons and holes are output as photocurrent signals from the infrared photodiode 1. Thus, the infrared rays are detected. At this time, in the infrared photodiode 1 of the embodiment, the substrate 20 has a majority-carrier-generating impurity concentration of 1×10¹⁷ cm⁻³ or more and 2×10²⁰ cm⁻³ or less, and the impurity has an activation ratio of 30% or more. As a result, sufficient carrier concentration is ensured in the substrate 20, to thereby achieve reduction in the power consumption. In addition, the substrate 20 has a decreased amount of unactivated impurity, so that sufficient sensitivity is ensured.

Incidentally, the p-electrode 92 is a pixel electrode. Referring to FIG. 2, the infrared photodiode 1 may include only one p-electrode 92 as a pixel electrode; alternatively, the infrared photodiode 1 may include plural pixel electrodes (p-electrodes 92). Specifically, the infrared photodiode 1 may have a structure in which unit structures each illustrated in FIG. 2 are repeated in the direction in which the main surface 20A of the substrate 20 extends in FIG. 2. In this case, the infrared photodiode 1 has plural p-electrodes 92 corresponding to pixels. The n-electrode 91 is continuously disposed so as to divide the antireflective film 85 into grid portions, when viewed in a direction perpendicular to the main surface of the antireflective film 85, viewed from a side of the antireflective film 85, the side being opposite to the substrate 20.

The infrared photodiode 1 is a mesa-type device in which the presence of the trench 99 forms a mesa including the quantum well layer 40 and the contact layer 50. However, the photodiode is not limited to this configuration and may have a planar-type configuration. When the planar-type configuration is employed, the following structure may be employed: formation of the trench 99 is omitted and the contact layer 50 is formed of, for example, InP (n-InP) into which Si is introduced as an impurity; and, for example, Zn is diffused in a region within the contact layer 50 and under the p-electrode 92, to invert the conductivity type of the region to the p-type.

Hereinafter, a method for producing the semiconductor layered structure 10 and the infrared photodiode 1 according to an embodiment will be outlined.

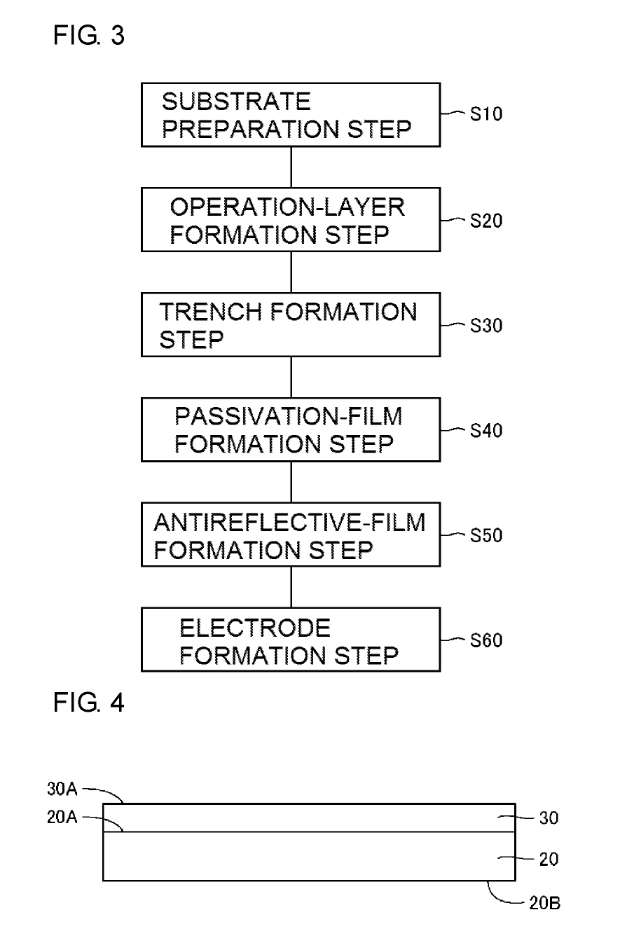

Referring to FIG. 3, in the method for producing the semiconductor layered structure 10 and the infrared photodiode 1 according to the embodiment, a substrate preparation step is first performed as Step (S10). In this Step (S10), referring to FIG. 4, a substrate 20 is prepared that has a diameter of 4 inches (101.6 mm) and is formed of InP, for example. More specifically, an ingot formed of InP is sliced to obtain the substrate 20 formed of InP. A surface of the substrate 20 is polished and then subjected to processes such as cleaning. Thus, the substrate 20 is prepared in which the planarity and cleanliness of a main surface 20A are ensured.

In this Step (S10), the substrate 20 is prepared that has a majority-carrier-generating impurity concentration of 1×10¹⁷ cm⁻³ or more and 2×10²⁰ cm⁻³ or less, the impurity having an activation ratio of 30% or more. Such a substrate 20 can be produced, for example, in the following manner: during production of an ingot formed of InP, an appropriate amount of S is added to achieve a S concentration of 1×10¹⁷ cm⁻³ or more and 2×10²⁰ cm⁻³ or less; and, during production of the ingot, for example, the temperature, the time for crystal growth, and proportions of supplied raw materials are appropriately controlled to achieve the activation ratio of the impurity (S) of 30% or more.

Subsequently, an operation-layer formation step is performed as Step (S20). In this Step (S20), on the main surface 20A of the substrate 20 prepared in Step (S10), a buffer layer 30, a quantum well layer 40, and a contact layer 50 are formed as operation layers. These operation layers can be formed by, for example, metal-organic vapor phase epitaxy. The formation of the operation layers by metal-organic vapor phase epitaxy can be performed by, for example, placing the substrate 20 on a rotation table equipped with a heater for heating a substrate, and, under heating of the substrate 20 with the heater, supplying source gases onto the substrate.

Specifically, referring to FIG. 4, the buffer layer 30 formed of, for example, n-InGaAs as a III-V compound semiconductor is first formed by metal-organic vapor phase epitaxy so as to be on and in contact with the main surface 20A of the substrate 20. In the formation of the buffer layer 30 formed of n-InGaAs, examples of the In source gas include TMIn (trimethylindium) and TEIn (triethylindium); examples of the Ga source gas include TEGa (triethylgallium) and TMGa (trimethylgallium); and examples of the As source gas include AsH₃ (arsine). TBAs (tertiarybutylarsine), and TMAs (trimethylarsine). When Si is added as an n-type impurity, for example. SiH₄ (silane), SiH₃(CH₃) (monomethylsilane), or TeESi (tetraethylsilane) may be added to a source gas.

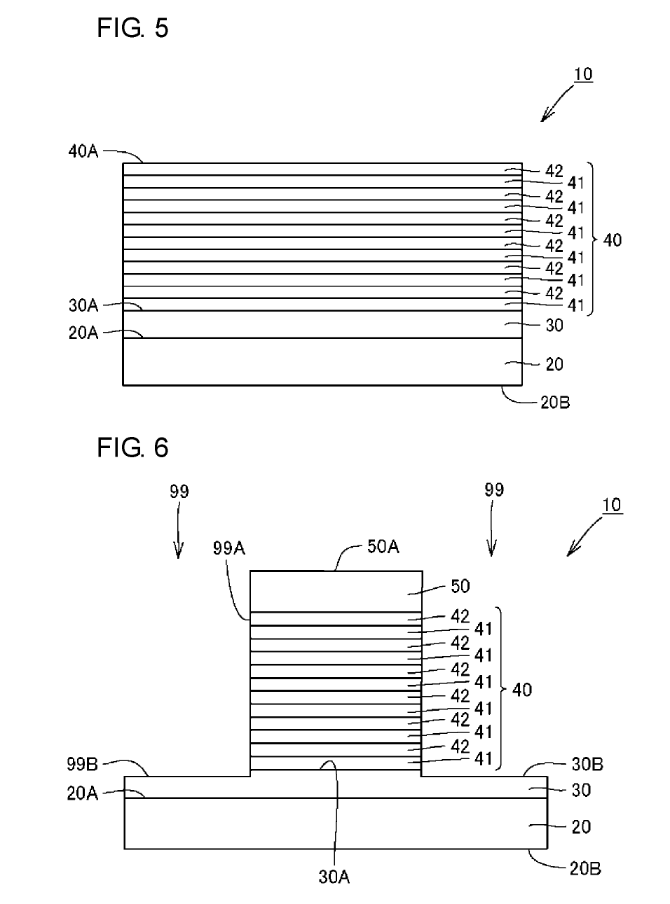

Subsequently, referring to FIGS. 4 and 5, the quantum well layer 40 is formed on and in contact with a main surface 30A of the buffer layer 30, the main surface 30A being on a side of the buffer layer 30 opposite to the other side facing the substrate 20, by alternately stacking, for example, a first component layer 41 formed of InGaAs as a III-V compound semiconductor and a second component layer 42 formed of GaAsSb as a III-V compound semiconductor.

Following the formation of the buffer layer 30, the quantum well layer 40 can be continuously formed by metal-organic vapor phase epitaxy. Specifically, while the substrate 20 is disposed within the apparatus having been used for forming the buffer layer 30, the source gases are changed to form the quantum well layer 40.

In the formation of the first component layers 41 formed of InGaAs, examples of the In source gas include TMIn and TEIn; examples of the Ga source gas include TEGa and TMGa: and examples of the As source gas include AsH₃, TBAs, and TMAs. In the formation of the second component layers 42 formed of GaAsSb, examples of the Ga source gas include TEGa and TMGa; examples of the As source gas include AsH₃, TBAs, and TMAs; and examples of the Sb source gas include TMSb (trimethylantimony), TESb (triethylantimony), TIPSb (triisopropylantimony), and TDMASb (trisdimethylaminoantimony). The first component layers 41 and the second component layers 42 may each be formed so as to have a thickness of, for example, 5 nm; and, for example, 250 unit structures each constituted by the first component layer 41 and the second component layer 42 may be stacked. As a result, a quantum well layer 40 that is a type-II quantum well can be formed. Here, for example, by controlling the flow rates of source gases to adjust the compositions of the compound semiconductors forming the quantum well layer 40, the first component layer 41 formed of InₓGa₁₋ₓAs (0.38≦x≦1) and the second component layer 42 formed of GaAs_{1-y}Sb_{y} (0.36≦y≦1) can be formed.

Subsequently, referring to FIGS. 5 and 1, the contact layer 50 formed of, for example, p-InGaAs as a III-V compound semiconductor is formed on and in contact with a main surface 40A of the quantum well layer 40, the main surface 40A being on a side of the quantum well layer 40 opposite to the other side facing the buffer layer 30. Following the formation of the quantum well layer 40, the contact layer 50 can be continuously formed by metal-organic vapor phase epitaxy. Specifically, while the substrate 20 is disposed within the apparatus having been used for forming the quantum well layer 40, the source gases are changed to form the contact layer 50. In the formation of the contact layer 50 formed of p-InGaAs, examples of the In source gas include TMIn and TEIn; examples of the Ga source gas include TEGa and TMGa; and examples of the As source gas include AsH₃, TBAs, and TMAs. When Zn is added as a p-type impurity, for example, DMZn (dimethylzinc) or DEZn (diethylzinc) can be added to a source gas.

The above-described procedures complete the semiconductor layered structure 10 of the embodiment. As described above, by performing Step (S20) by metal-organic vapor phase epitaxy, the semiconductor layered structure 10 including operation layers having high crystallinity can be efficiently produced. The Step (S20) may be performed by metal-organic vapor phase epitaxy using only metal-organic sources, which does not use, for example, hydrides such as AsH₃. Alternatively, Step (S20) can be performed by a method other than metal-organic vapor phase epitaxy. For example, MBE (Molecular Beam Epitaxy) may be used.

Subsequently, referring to FIG. 3, a trench formation step is performed as Step (S30). In this Step (S30), referring to FIGS. 1 and 6, in the semiconductor layered structure 10 produced by Steps (S10) and (S20) above, a trench 99 is formed so as to extend through the contact layer 50 and the quantum well layer 40 to reach the buffer layer 30. The trench 99 can be formed by, for example, forming a mask layer having an opening corresponding to the shape of the trench 99, on a main surface 50A of the contact layer 50, and then performing etching.

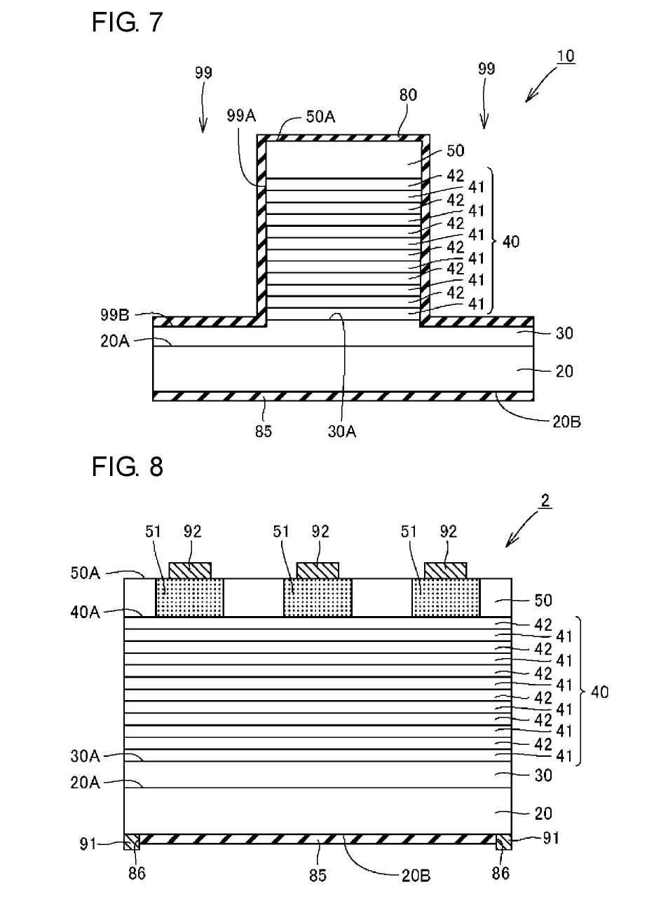

Subsequently, a passivation-film formation step is performed as Step (S40). In this Step (S40), referring to FIGS. 6 and 7, in the semiconductor layered structure 10 having the trench 99 formed in Step (S30), a passivation film 80 is formed. Specifically, for example, CVD (Chemical Vapor Deposition) is performed to form the passivation film 80 formed of an insulator such as silicon oxide or silicon nitride. The passivation film 80 is formed so as to cover a bottom wall 99B of the trench 99, a side wall 99A of the trench 99, and the main surface 50A of the contact layer 50, the main surface 50A being on a side of the contact layer 50 opposite to the other side facing the quantum well layer 40.

Subsequently, an antireflective-film formation step is performed as Step (S50). In this Step (S50), referring to FIG. 7, an antireflective film 85 is formed on the semiconductor layered structure 10 having the passivation film 80 formed in Step (S40). Specifically, for example, CVD is performed to form the antireflective film 85 formed of silicon oxynitride. The antireflective film 85 is formed so as to cover a main surface 20B of the substrate 20, the main surface 20B being on a side of the substrate 20 opposite to the buffer layer 30.

Subsequently, an electrode formation step is performed as Step (S60). In this Step (S60), referring to FIGS. 7 and 2, in the semiconductor layered structure 10 having the passivation film 80 and the antireflective film 85 formed in Steps (S40) and (S50), an n-electrode 91 and a p-electrode 92 are formed. Specifically, for example, masks having openings at positions corresponding to regions where the n-electrode 91 and the p-electrode 92 are to be formed, are formed on the passivation film 80 and the antireflective film 85; and the passivation film 80 and the antireflective film 85 are etched through the masks to form openings 81 and 86. After that, for example, vapor deposition is performed to form the n-electrode 91 and the p-electrode 92 formed of appropriate electric conductors. The steps having been described complete the infrared photodiode 1 according to the embodiment. After that, for example, dicing is performed to provide separate devices.

### EXAMPLES

An experimental infrared photodiode was produced, the photodiode being configured to detect, on the basis of transfer of carriers (electrons) in the thickness direction of the substrate, infrared rays entering the photodiode through the substrate. And, an experiment was performed for examining the relationship between the majority-carrier-generating impurity concentration of the substrate, the activation ratio of the impurity, sensitivity, and power consumption. The procedures of the experiment are as follows.

Referring to FIG. 8, the structure of the experimental infrared photodiode will be first described. An experimental infrared photodiode 2 includes a substrate 20 formed of InP; a buffer layer 30 formed on the substrate 20 and formed of nGaAs; a quantum well layer 40 formed on the buffer layer 30, in which a first component layer 41 formed of InGaAs and a second component layer formed of GaAsSb are alternately stacked; and a contact layer 50 formed of InP. The substrate 20 to which S is introduced as an impurity has an n-type conductivity. The buffer layer 30 to which Si is introduced as an impurity has an n-type conductivity. The contact layer 50 to which Si is introduced as an impurity has an n-type conductivity.

An antireflective film 85 is formed on a main surface 20B of the substrate 20, the main surface 20B being on a side of the substrate 20 opposite to the buffer layer 30, so as to cover the main surface 20B. The antireflective film 85 has an opening 86 extending through the antireflective film 85 in the thickness direction. An n-electrode 91 formed of an electric conductor is disposed so as to fill the opening 86. On the other hand, p-electrodes 92 formed of an electric conductor are disposed on and in contact with a main surface 50A of the contact layer 50, the main surface 50A being on a side of the contact layer 50 opposite to the quantum well layer 40. Diffusion regions 51 are formed in regions within the contact layer 50 and under the p-electrodes 92, the regions being formed by introduction of Zn through diffusion so that the conductivity type has been inverted to the p-type.

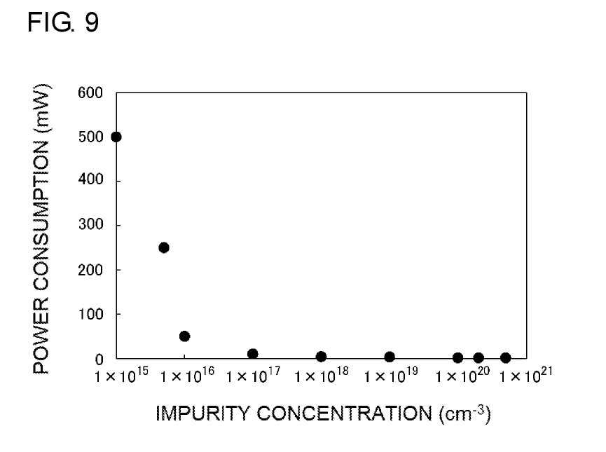

Regarding such an experimental infrared photodiode 2 having the above-described structure, the impurity concentration (concentration of S) of the substrate 20 and the activation ratio of the impurity were varied to produce plural experimental infrared photodiodes 2 differing in the carrier concentration of the substrate 20. The impurity concentrations of the substrates 20 were determined by SIMS. The carrier concentrations were determined by examining C-V characteristics. While infrared rays of a wavelength of 2 μm were caused to enter each experimental infrared photodiode 2 through the substrate 20, the sensitivity was examined and the power consumption was examined. The experimental results are described in Tables 1 and 2 and FIG. 9.

TABLE 1

| Impurity concentration (cm⁻³) | 3 × 10²⁰ | 2 × 10²⁰ | 1 × 10²⁰ | 1 × 10¹⁹ | 1 × 10¹⁸ | 1 × 10¹⁷ | 1 × 10¹⁶ | 5 × 10¹⁵ | 1 × 10¹⁴ |
|---|---|---|---|---|---|---|---|---|---|
| Sensitivity λ = 2 μm | C | B | A | A+ | A+ | A+ | A+ | A+ | A+ |
| Power consumption (mW) | 1 | 1 | 1 | 3 | 4 | 10 | 50 | 250 | 500 |

TABLE 2

| Impurity concentration (cm⁻³) | 6.0 × 10¹⁸ | | | |
|---|---|---|---|---|
| Activation ratio | 20% | 30% | 50% | 80% |
| Sensitivity λ = 2 μm | C | B+ | A | A+ |

Table 1 describes sensitivity (sensitivity to light of a wavelength of 2 μm) and power consumption when the substrates 20 have the same activation ratio and different majority-carrier-generating impurity concentrations. In the experiment of Table 1, the activation ratio is 80%. Table 2 describes sensitivity when the substrates 20 have the same majority-carrier-generating impurity concentration and different activation ratios. Table 1 and Table 2 describe sensitivity as follows: A represents sufficient sensitivity; A+ represents higher sensitivity than A; B+ represents lower sensitivity than A but allowable sensitivity; B represents lower sensitivity than B+ but allowable sensitivity; and C represents insufficient sensitivity. In FIG. 9, the abscissa axis indicates the majority-carrier-generating impurity concentration of the substrate, and the ordinate axis indicates power consumption. FIG. 9 illustrates the relationship between majority-carrier-generating impurity concentration and power consumption in Table 1.

Referring to Table 1 and FIG. 9, when the majority-carrier-generating impurity concentration is 1×10¹⁸ cm⁻³ or more, the power consumption is a sufficiently low value, specifically 4 mW or less. When the majority-carrier-generating impurity concentration is 1×10¹⁷ cm⁻³, the power consumption is 10 mW, which is somewhat higher but still within the allowable range. However, when the majority-carrier-generating impurity concentration is less than 1×10¹⁷ cm⁻³, the power consumption sharply increases. In summary, from the viewpoint of power consumption, the majority-carrier-generating impurity concentration of the substrate 20 is preferably 1×10¹⁷ cm⁻³ or more, more preferably 1×10¹⁸ cm⁻³ or more. Next, the sensitivity in Table 1 will be considered. In spite of the same activation ratio, when the majority-carrier-generating impurity concentration is 3×10²⁰ cm⁻³, which is more than 2×10²⁰ cm⁻³, the sensitivity is evaluated as being insufficient (Evaluation: C); in contrast, when the majority-carrier-generating impurity concentration is 2×10²⁰ cm⁻³, an allowable sensitivity is obtained (Evaluation: B). When the majority-carrier-generating impurity concentration is 1×10²⁰ cm⁻³ or less, an increase in the sensitivity is observed (Evaluation: A or better); and in the case of 1×10¹⁹ cm⁻³ or less, a further increase in the sensitivity is observed (Evaluation: A+). In summary, in order to obtain sufficient sensitivity, the majority-carrier-generating impurity concentration needs to be set to 2×10²⁰ cm⁻³ or less; in order to obtain sufficient sensitivity with more certainty, the majority-carrier-generating impurity concentration of the substrate is preferably set to 1×10²⁰ cm⁻³ or less, more preferably to 1×10¹⁹ cm⁻³ or less.

On the other hand, for the purpose of confirming the findings of the inventors of the present invention that variations in the sensitivity are observed in spite of equivalent majority-carrier-generating impurity concentrations, the influence of the activation ratio will be discussed with reference to Table 2. As described in Table 2, when the activation ratio is 20%, which is less than 30%, the sensitivity is insufficient (Evaluation: C). On the other hand, when the activation ratio is set to 30% or more, allowable sensitivities are obtained (Evaluation: B+ or better). This indicates that the activation ratio needs to be set to 30% or more. Furthermore, with reference to Table 2, in spite of the same majority-carrier-generating impurity concentration, an activation ratio of 50% or more provides an increase in the sensitivity (Evaluation: A), and an activation ratio of 80% or more provides a sensitivity (Evaluation: A+) better than the sensitivity in the case of 50%. This indicates that the activation ratio of the majority-carrier-generating impurity of the substrate is preferably set to 50% or more, more preferably 80% or more.

The above-described experimental results have demonstrated that, by setting the majority-carrier-generating impurity concentration of the substrate to 1×10¹⁷ cm⁻³ or more and 2×10²⁰ cm⁻³ or less and by setting the activation ratio of the impurity to 30% or more, sufficient sensitivity is ensured and reduction in the power consumption is also achieved in the photodiode.

The embodiments and EXAMPLES disclosed herein are mere examples in all respects and should be understood as being non-limitative in any perspective. The scope of the present invention is defined not by the above-described description but by Claims. The scope of the present invention is intended to embrace all the modifications within the meaning and range of equivalency of the Claims.

### INDUSTRIAL APPLICABILITY

In particular, a semiconductor layered structure and a photodiode according to the present application are advantageously applicable to a semiconductor layered structure and a photodiode that include a substrate and a semiconductor layer formed of III-V compound semiconductors.

### REFERENCE SIGNS LIST

1 infrared photodiode; 2 experimental infrared photodiode; 10 semiconductor layered structure; 20 substrate; 20A main surface; 20B main surface; 30 buffer layer; 30A main surface; 40 quantum well layer; 40A main surface; 41 first component layer; 42 second component layer; 50 contact layer; 50A main surface; 51 diffusion region; 80 passivation film; 81 opening; 85 antireflective film; 86 opening; 91 n-electrode; 92 p-electrode; 99 trench; 99A side wall; 99B bottom wall.

1. A semiconductor layered structure comprising:
a substrate formed of a III-V compound semiconductor; and
a semiconductor layer disposed on the substrate and formed of a III-V compound semiconductor,
wherein the substrate has a majority-carrier-generating impurity concentration of 1×10¹⁷ cm⁻³ or more and 2×10²⁰ cm⁻³ or less, and the impurity has an activation ratio of 30% or more.

2. The semiconductor layered structure according to claim 1, wherein the substrate has an n-type conductivity.

3. The semiconductor layered structure according to claim 1, wherein the semiconductor layer includes a quantum well layer.

4. The semiconductor layered structure according to claim 3, wherein the quantum well layer has a thickness of 1 μm or more.

5. The semiconductor layered structure according to claim 3, wherein the quantum well layer has a structure in which an InₓGa₁₋ₓAs (0.38≦x≦1) layer and a GaAs_{1-y}Sb_{y} (0.36≦y≦1) layer are alternately stacked, or has a structure in which a Ga₁₋ᵤInᵤNᵥAs₁₋ᵥ (0.4≦u≦0.8, 0<v≦0.2) layer and a GaAs_{1-y}Sb_{y} (0.36≦y≦0.62) layer are alternately stacked.

6. The semiconductor layered structure according to claim 1, wherein the III-V compound semiconductor forming the substrate is GaAs, GaP, GaSb, InP, InAs, InSb, AlSb, or AlAs.

7. The semiconductor layered structure according to claim 1, wherein the semiconductor layer is formed by metal-organic vapor phase epitaxy.

8. A photodiode comprising:
the semiconductor layered structure according to claim 1; and
an electrode formed on a main surface of the substrate of the semiconductor layered structure, the main surface being on a side of the substrate opposite to the semiconductor layer.
